(19) United States
(12) Patent Application Publication
(10) Pub. No.: US 2026/0068500 A1
(43) Pub. Date: Mar. 5, 2026

(54) Display Apparatus

(71) Applicant: LG Display Co., Ltd., Seoul (KR)

(72) Inventors: Seungpyo Hong, Busan (KR); YunHo Kook, Goyang-si (KR); Jonghan Park, Seoul (KR); Jihyang Yoon, Ulsan (KR)

(21) Appl. No.: 19/261,328

(22) Filed: Jul. 7, 2025

(30) Foreign Application Priority Data
Sep. 2, 2024 (KR) 10-2024-0118461

(51) Int. Cl. H10K 59/80; H10K 59/122

(52) U.S. Cl. CPC H10K 59/8731; H10K 59/122; H10K 59/80515

(57) ABSTRACT

A display apparatus includes an over coating layer including a base portion and a protrusion that has an inclined side surface, a first electrode in a sub pixel and covering a part of the base portion and a part of the protrusion, a bank on the first electrode and the protrusion and exposing a part of the first electrode, an organic layer on the first electrode and the bank, a second electrode on the organic layer, and an encapsulation unit on the second electrode and includes a first inorganic encapsulation layer on the second electrode, a first organic encapsulation layer on the first inorganic encapsulation layer, a second organic encapsulation layer on the first organic encapsulation layer, and a second inorganic encapsulation layer on the second organic encapsulation layer. The first organic encapsulation layer includes a concave portion that overlaps the exposed part of the first electrode.

### CROSS-REFERENCE TO RELATED APPLICATION

This application claims the priority of Republic of Korea Patent Application No. 10-2024-0118461 filed on Sep. 2, 2024, which is hereby incorporated by reference in its entirety.

### BACKGROUND

### Field

The present disclosure relates to a display apparatus, and more particularly, to a display apparatus in which a luminance deviation according to a viewing angle is minimized or at least reduced.

### Description of the Related Art

Currently, as it enters a full-scale information era, a field of a display apparatus which visually expresses electrical information signals has been rapidly developed and studies are continued to improve performances of various display apparatuses such as a thin-thickness, a light weight, and low power consumption.

Among various display apparatuses, an organic light emitting display apparatus is a self-emitting display apparatus so that a separate light source is not necessary, which is different from the liquid crystal display apparatus. Therefore, the organic light emitting display apparatus may be manufactured to have a light weight and a small thickness. Further, since the display apparatus is driven at a low voltage so that it is advantageous not only in terms of power consumption, but also in terms of color implementation, a response speed, a viewing angle, and a contrast ratio (CR). Therefore, it is expected to be utilized in various fields.

### SUMMARY

An object to be achieved by the present disclosure is to provide a display apparatus which improves a viewing angle by refracting a path of light to a side direction of a sub pixel.

Another object to be achieved by the present disclosure is to provide a low-power display apparatus in which a luminance deviation according to a viewing angle is reduced to improve color reproducibility and reduce power consumption.

Objects of the present disclosure are not limited to the above-mentioned objects, and other objects, which are not mentioned above, can be clearly understood by those skilled in the art from the following descriptions.

In one embodiment, a display apparatus comprises: a substrate including a plurality of sub pixels; an over coating layer on the substrate, the over coating layer including a base portion and a protrusion that protrudes from the base portion in a direction away from the substrate and has an inclined side surface with respect to the base portion; a first electrode in a sub pixel from the plurality of sub pixels, the first electrode covering a part of the base portion and a part of the protrusion; a bank on the first electrode and the protrusion, the bank having an opening that exposes a part of the first electrode; an organic layer on the first electrode and the bank; a second electrode on the organic layer; and an encapsulation unit on the second electrode, the encapsulation unit including a first inorganic encapsulation layer on the second electrode, a first organic encapsulation layer on the first inorganic encapsulation layer, a second organic encapsulation layer on the first organic encapsulation layer, and a second inorganic encapsulation layer on the second organic encapsulation layer, wherein a refractive index of the second organic encapsulation layer is different from a refractive index of the first organic encapsulation layer, wherein the first organic encapsulation layer includes a concave portion that overlaps the exposed part of first electrode.

In one embodiment, a display apparatus comprises: a substrate including an active area in which a plurality of sub pixels are disposed and a non-active area; an over coating layer on the substrate, the over coating layer including a base portion and a protrusion that protrudes from the base portion in a direction away from the substrate and has an inclined side surface; a first electrode in a sub pixel from the plurality of sub pixels, the first electrode covering the base portion and a part of the protrusion; a bank on the first electrode, the bank having an opening that exposes a part of the first electrode; an organic layer on the first electrode and the bank; a second electrode on the organic layer; and an encapsulation unit on the second electrode, the encapsulation unit including a first inorganic encapsulation layer on the second electrode, a first organic encapsulation layer on the first inorganic encapsulation layer, a second organic encapsulation layer on the first organic encapsulation layer and having a refractive index that is lower than a refractive index of the first organic encapsulation layer, and a second inorganic encapsulation layer on the second organic encapsulation layer, wherein the sub pixel includes a first emission area corresponding to an area where the part of the first electrode is exposed from the bank, and wherein the first organic encapsulation layer includes a concave portion that overlaps the exposed part of first electrode.

In one embodiment, a display apparatus comprises: a substrate; a transistor on the substrate; a light-emitting element that is electrically connected to the transistor, the light-emitting element including a first electrode, an organic layer on the first electrode, and a second electrode on the organic layer; a bank on the first electrode of the light-emitting element, the bank including an opening that exposes a part of the first electrode; and an encapsulation unit over the light-emitting element, the encapsulation unit including a first inorganic encapsulation layer on the second electrode of the light-emitting element, a first organic encapsulation layer on the first inorganic encapsulation layer that has a concave portion that extends in a direction toward the substrate, a second organic encapsulation layer on the concave portion of the first inorganic encapsulation layer, and a second inorganic encapsulation layer on the second organic encapsulation layer, wherein the concave portion of the first organic encapsulation layer overlaps the exposed part of the first electrode.

Other detailed matters of the exemplary embodiments are included in the detailed description and the drawings.

According to the present disclosure, a first organic encapsulation layer includes a concave portion and a second organic encapsulation layer has a refractive index different from that of the first organic encapsulation layer, so as to refract the path of light to the side direction.

According to the present disclosure, the path of light is refracted to the side direction of the sub pixel to improve the viewing angle of the display apparatus.

The effects according to the present disclosure are not limited to the contents exemplified above, and more various effects are included in the present specification.

### BRIEF DESCRIPTION OF DRA WINGS

The above and other aspects, features and other advantages of the present disclosure will be more clearly understood from the following detailed description taken in conjunction with the accompanying drawings, in which:

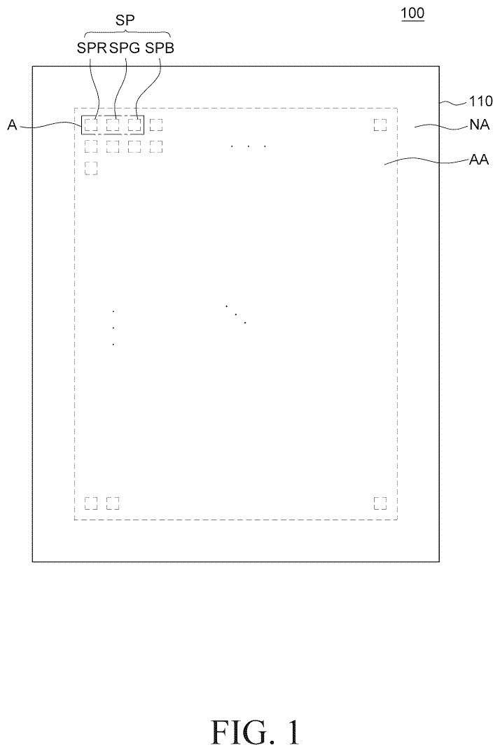

FIG. 1 is a plan view of a display apparatus according to an exemplary embodiment of the present disclosure;

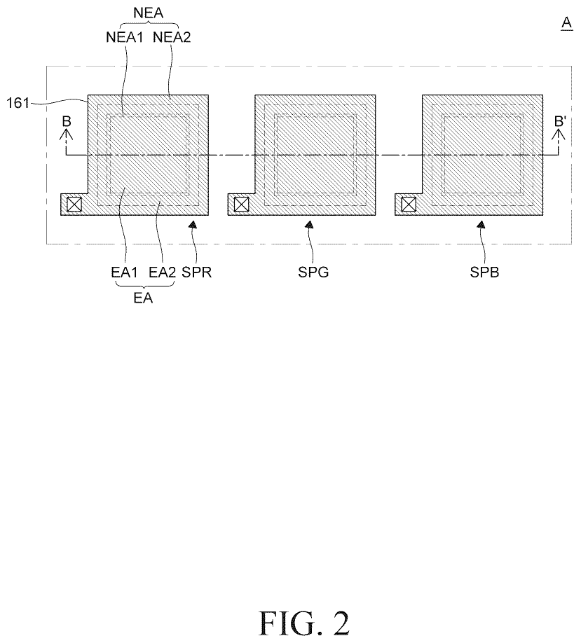

FIG. 2 is an enlarged plan view of an area A of FIG. 1 according to an exemplary embodiment of the present disclosure;

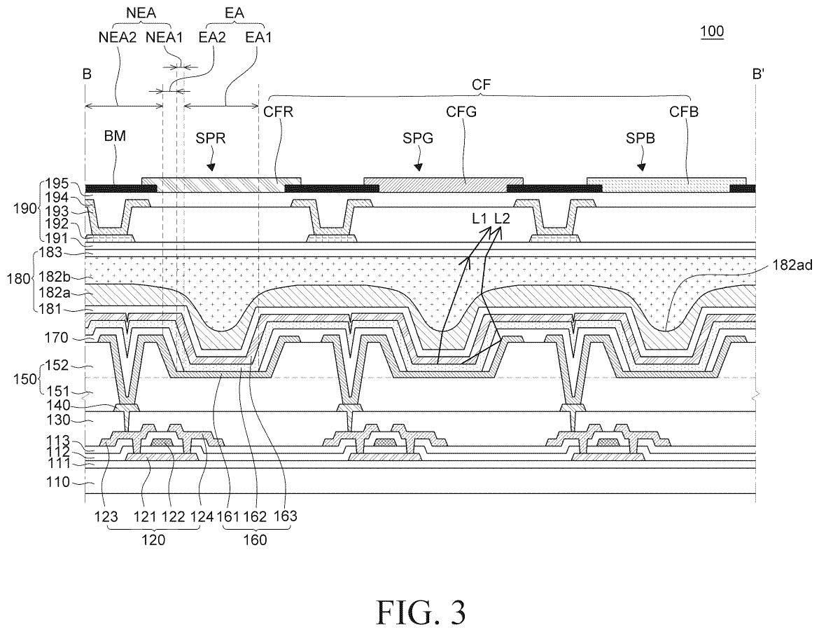

FIG. 3 is a cross-sectional view of a display apparatus taken along B-B′ of FIG. 2 according to an exemplary embodiment of the present disclosure;

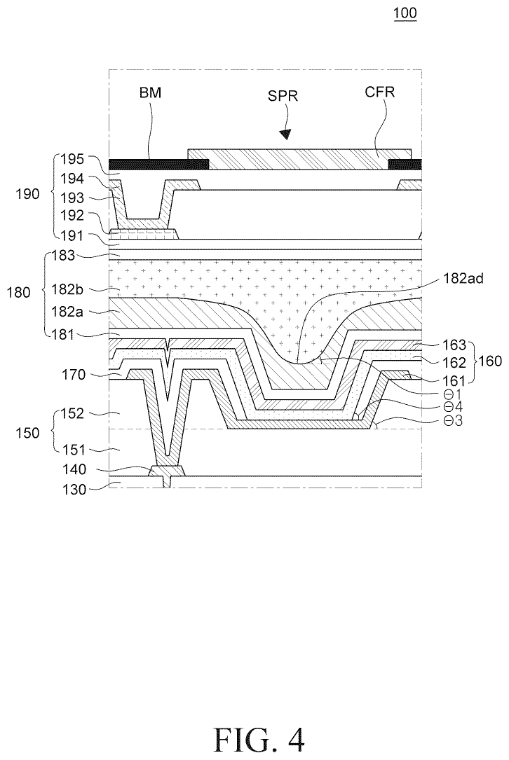

FIG. 4 is an enlarged cross-sectional view of one sub pixel of a display apparatus according to an exemplary embodiment of the present disclosure;

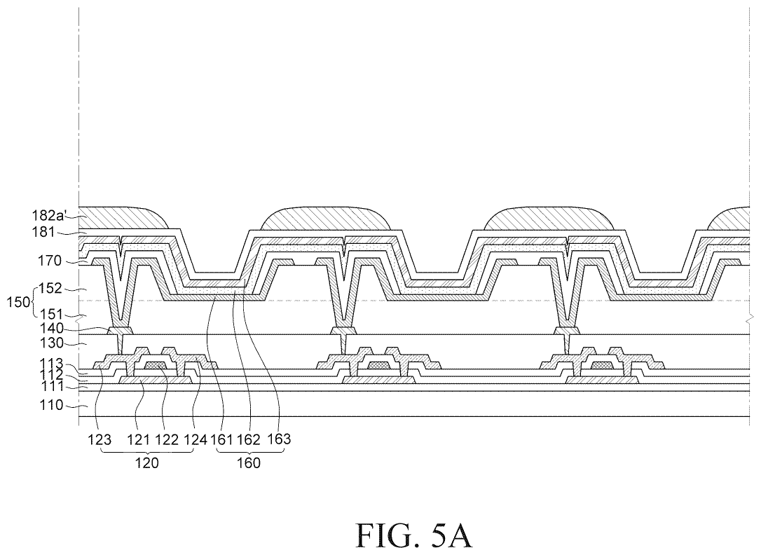

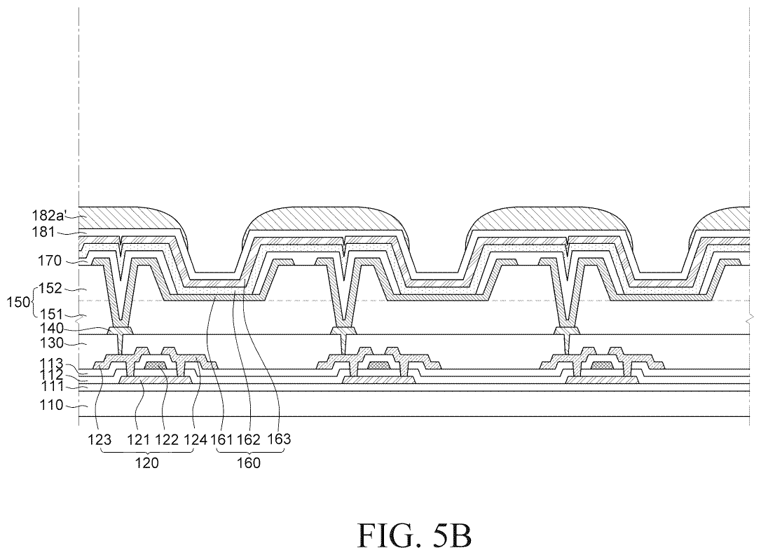

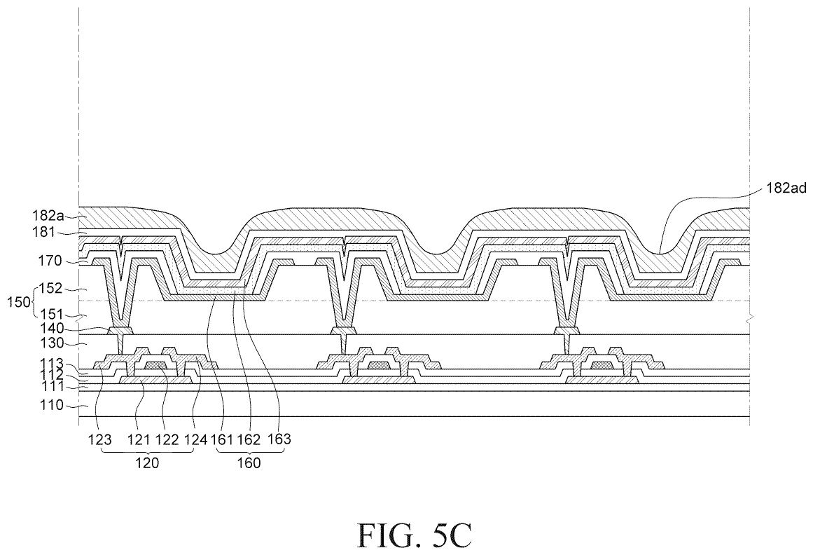

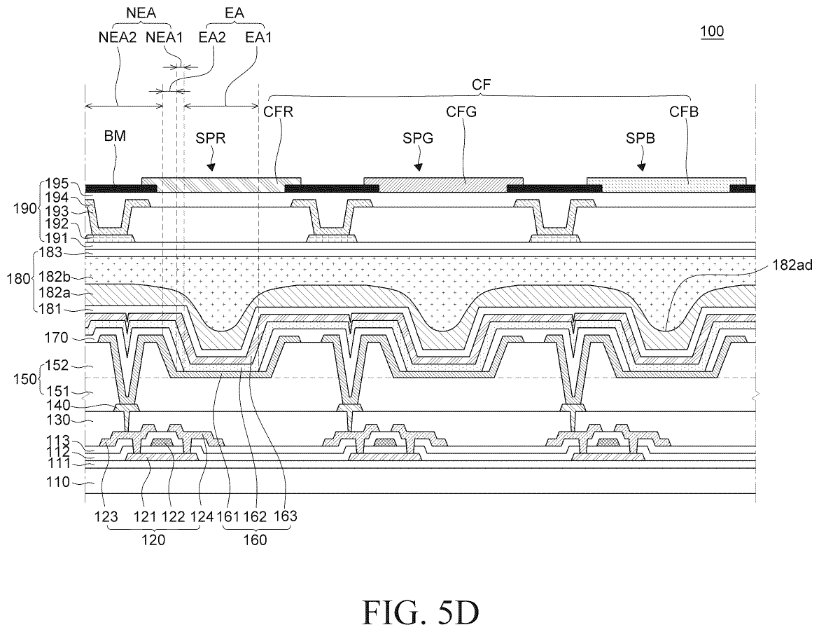

FIGS. 5A to 5D are process flowcharts of a display apparatus according to an exemplary embodiment of the present disclosure;

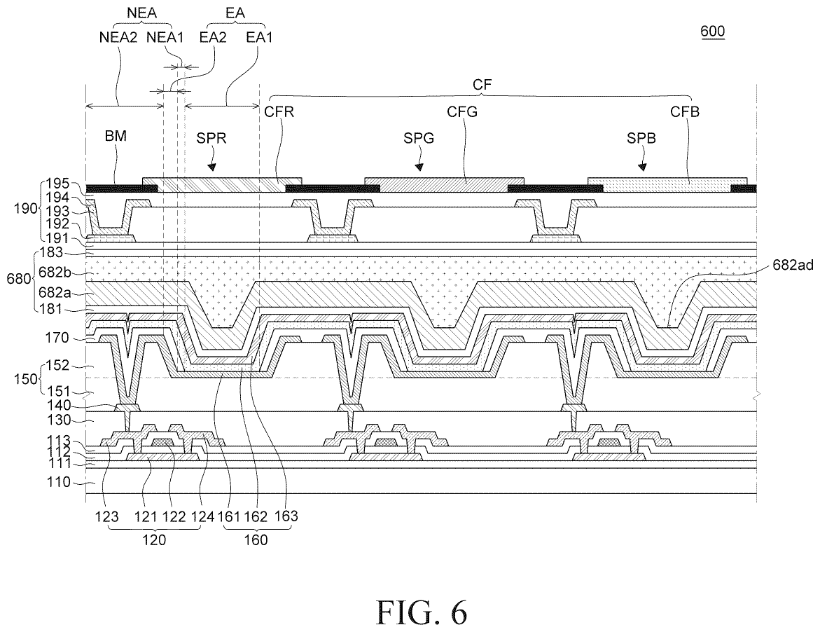

FIG. 6 is a cross-sectional view of a display apparatus according to another exemplary embodiment of the present disclosure;

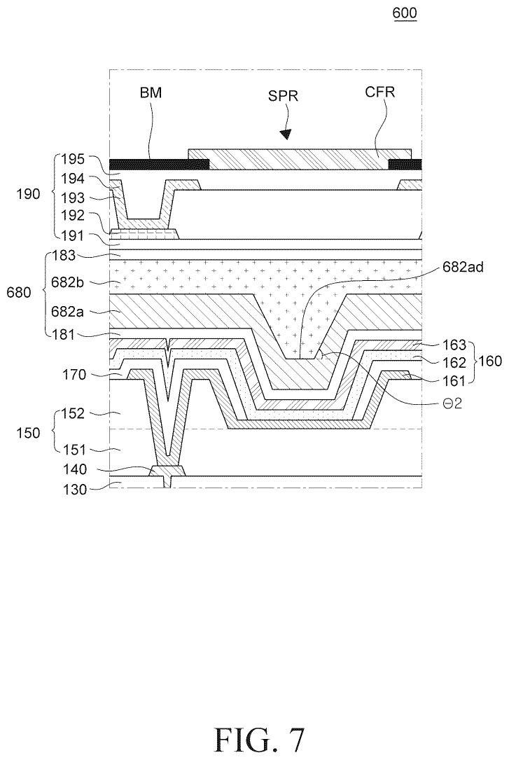

FIG. 7 is an enlarged cross-sectional view of one sub pixel of a display apparatus according to another exemplary embodiment of the present disclosure; and

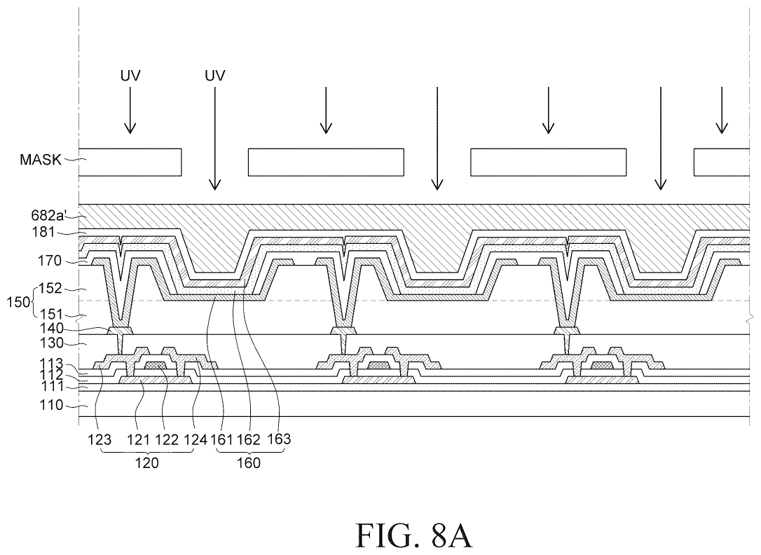

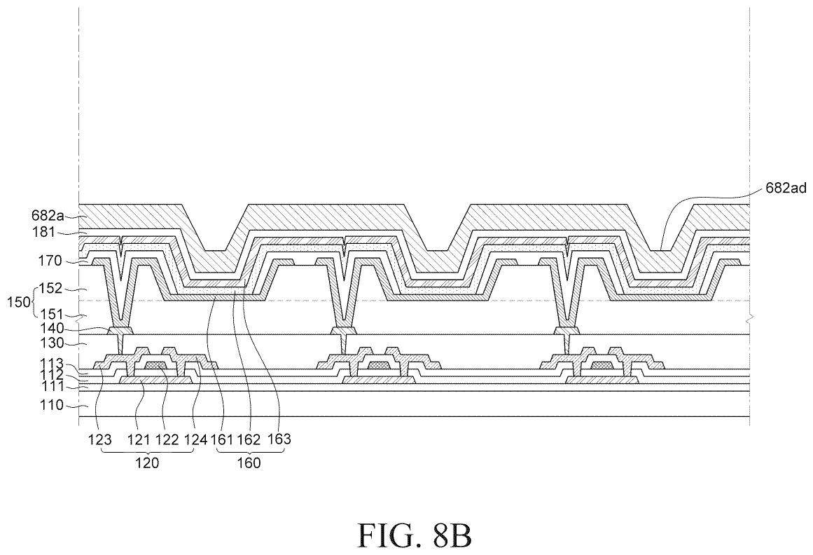

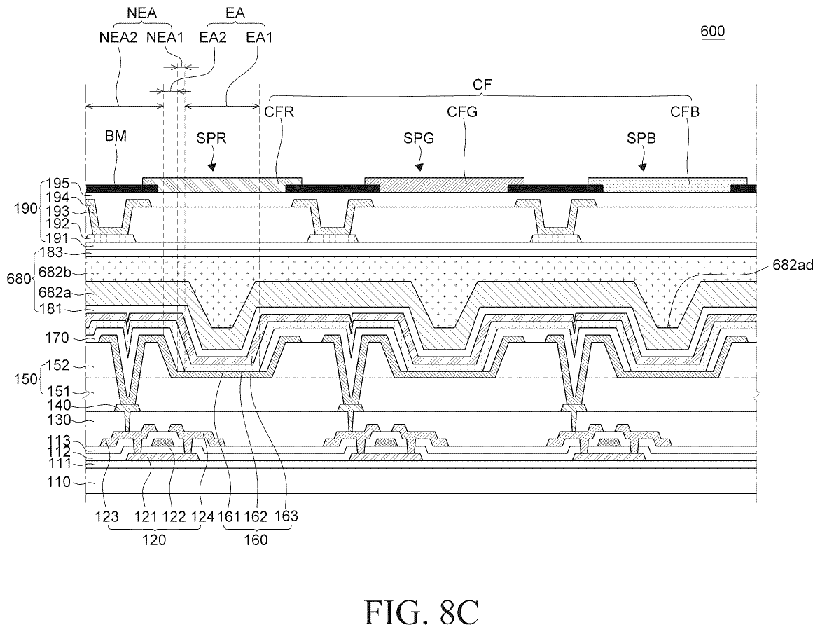

FIGS. 8A to 8C are process flowcharts of a display apparatus according to another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as ‘including’, ‘having’, ‘comprising’ used herein are generally intended to allow other components to be added unless the terms are used with the term ‘only’. Any references to singular may include plural unless expressly stated otherwise.

Components are interpreted to include an ordinary error range even if not expressly stated.

When the position relation between two parts is described using the terms such as ‘on’, ‘above’, ‘below’, ‘next’, one or more parts may be positioned between the two parts unless the terms are used with the term ‘immediately’ or ‘directly’.

When an element or layer is disposed “on” another element or layer, another layer or another element may be interposed therebetween or it may be directly on the another element or layer.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Same reference numerals generally denote same elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to accompanying drawings.

FIG. 1 is a plan view of a display apparatus according to an exemplary embodiment of the present disclosure. FIG. 2 is an enlarged plan view of an area A of FIG. 1 according to an exemplary embodiment of the present disclosure. FIG. 3 is a cross-sectional view of a display apparatus taken along B-B′ of FIG. 2 according to an exemplary embodiment of the present disclosure. FIG. 4 is an enlarged cross-sectional view of one sub pixel of a display apparatus according to an exemplary embodiment of the present disclosure.

Referring to FIGS. 1 to 4, the display apparatus 100 includes a substrate 110, a transistor 120, a first over coating layer 130, an auxiliary electrode 140, a second over coating layer 150, a light emitting diode 160 (e.g., a light emitting element), a bank 170, an encapsulation unit 180, a touch unit 190, a black matrix BM, and a color filter CF. The display apparatus 100 may be implemented as a top emission type display apparatus, but is not limited thereto.

The substrate 110 is a substrate which supports and protects a plurality of components of the display apparatus 100. The substrate 110 may be formed of a glass or a plastic material having flexibility. When the substrate 110 is formed of a plastic material, for example, the substrate may be formed of polyimide (PI), but it is not limited thereto.

The substrate 110 includes an active area AA and a non-active area NA.

The active area AA is an area in which an image is displayed in the display apparatus 100 and a display element and various driving elements for driving the display element may be disposed in the active area AA. For example, the display element may be configured by a light emitting diode 160 including a first electrode 161, an organic layer 162, and a second electrode 163. Further, various driving elements for driving the display element, such as a transistor 120, a capacitor, or wiring lines may be disposed in the active area AA.

A plurality of sub pixels SP may be included in the active area AA. The sub pixel SP is a minimum unit which configures a screen and each of the plurality of sub pixels SP may include a light emitting diode 160 and a driving circuit. The plurality of sub pixels SP may emit light having different wavelengths. For example, the plurality of sub pixels SP may include a red sub pixel SPR, a green sub pixel SPG, and a blue sub pixel SPB. Further, the plurality of sub pixels SP may further include a white sub pixel.

The driving circuit of the sub pixel SP is a circuit for controlling the driving of the light emitting diode 160. For example, the driving circuit may be configured to include the transistor 120 and the capacitor, but is not limited thereto.

The non-active area NA is an area where no image is displayed and various components for driving the plurality of sub pixels SP disposed in the active area AA may be disposed in the non-active area NA. For example, a driving IC which supplies a signal for driving the plurality of sub pixels SP and a flexible film may be disposed.

The non-active area NA may be an area which encloses the active area AA as illustrated in FIG. 1, but is not limited thereto. For example, the non-active area NA may be an area extending from the active area AA.

Hereinafter, the plurality of sub pixels SP disposed in the active area AA will be described in more detail with reference to FIG. 2.

Referring to FIG. 3, a buffer layer 111 is disposed on the substrate 110. The buffer layer 111 may serve to improve adhesive strength between layers formed on the buffer layer 111 and the substrate 110 and block alkali components leaked from the substrate 110. The buffer layer 111 may be formed as a single layer of silicon nitride (SiNx) or silicon oxide (SiOx) or multiple layers of silicon nitride (SiNx) and silicon oxide (SiOx), but is not limited thereto. The buffer layer 111 is not an essential component and may be omitted based on a type or a material of the substrate 110 and a structure and a type of the transistor 120.

The transistor 120 is disposed on the buffer layer 111. The transistor 120 may be used as a driving element which drives the light emitting diode 160 of the active area AA. The transistor 120 includes an active layer 121, a gate electrode 122, a source electrode 123, and a drain electrode 124. The transistor 120 illustrated in FIG. 3 is a driving transistor and is a top gate type thin film transistor in which the gate electrode 122 is disposed on the active layer 121. However, it is not limited thereto and the transistor 120 may be implemented as a bottom gate type transistor.

The active layer 121 is disposed on the buffer layer 111. The active layer 121 is an area in which a channel is formed when the transistor 120 is driven. The active layer 121 may be formed of an oxide semiconductor or amorphous silicon (a-Si), polycrystalline silicon (poly-Si), or an organic semiconductor.

The gate insulating layer 112 is disposed on the active layer 121. The gate insulating layer 112 is a layer for electrically insulating the gate electrode 122 from the active layer 121 and may be formed of an insulating material. For example, the gate insulating layer 112 may be formed as a single layer of silicon nitride (SiNx) or silicon oxide (SiOx) which is an inorganic material or r of silicon nitride (SiNx) and silicon oxide (SiOx), but it is not limited thereto.

In the gate insulating layer 112, a contact hole through which the source electrode 123 and the drain electrode 124 are in contact with a source region and a drain region of the active layer 121, respectively, is formed. The gate insulating layer 112 may be formed on the entire surface of the substrate 110 as illustrated in FIG. 2 or patterned to have the same width as the gate electrode 122, but is not limited thereto.

The gate electrode 122 is disposed on the gate insulating layer 112. The gate electrode 122 is disposed on the gate insulating layer 112 so as to overlap a channel region of the active layer 121. The gate electrode 122 may be any one of various metal materials, for example, any one of molybdenum (Mo), aluminum (Al), chrome (Cr), gold (Au), titanium (Ti), nickel (Ni), neodymium (Nd), and copper (Cu) or an alloy of two or more of them, or multiple layers thereof, but it is not limited thereto.

The interlayer insulating layer 113 is disposed on the gate electrode 122. The interlayer insulating layer 113 may be formed as a single layer of silicon nitride (SiNx) or silicon oxide (SiOx) which is an inorganic material or multiple layers of silicon nitride (SiNx) and silicon oxide (SiOx), but it is not limited thereto. In the interlayer insulating layer 113, a contact hole through which the source electrode 123 and the drain electrode 124 are in contact with the source region and the drain region of the active layer 121, respectively, is formed.

The source electrode 123 and the drain electrode 124 are disposed on the interlayer insulating layer 113. The source electrode 123 and the drain electrode 124 are disposed on the same layer to be spaced apart from each other. The source electrode 123 and the drain electrode 124 are electrically connected to the active layer 121 through the contact holes of the gate insulating layer 112 and the interlayer insulating layer 113. The source electrode 123 and the drain electrode 124 may be any one of various metal materials such as molybdenum (Mo), aluminum (Al), chrome (Cr), gold (Au), titanium (Ti), nickel (Ni), neodymium (Nd), and copper (Cu) or an alloy of two or more of them, or multiple layers thereof, but the present disclosure is not limited thereto.

In FIG. 3, a driving transistor, among various transistors 120 included in the display apparatus 100, is illustrated, but other transistors such as a switching transistor may also be disposed.

The first over coating layer 130 is disposed on the interlayer insulating layer 113 and the transistor 120. The first over coating layer 130 is an insulating layer which protects the transistor 120 and planarizes an upper portion of the transistor 120. A contact hole which exposes the source electrode 123 of the transistor 120 is formed on the first over coating layer 130. Even though in FIG. 3, it is illustrated that a contact hole which exposes the source electrode 123 is formed on the first over coating layer 130, it is not limited thereto. For example, a contact hole which exposes the drain electrode 124 may be formed on the first over coating layer 130.

The first over coating layer 130 may be formed of one of acrylic resin, epoxy resin, phenol resin, polyamide resin, polyimide resin, unsaturated polyester resin, polyphenylene resin, polyphenylene sulfide resin, benzocyclobutene, and photoresist, but is not limited thereto.

A passivation layer which covers the interlayer insulating layer 113 and the transistor 120 may be further disposed below the first over coating layer 130. The passivation layer may be formed as a single layer of silicon nitride (SiNx) or silicon oxide (SiOx) or multiple layers of silicon nitride (SiNx) and silicon oxide (SiOx), but it is not limited thereto.

The auxiliary electrode 140 is disposed on the first over coating layer 130. The auxiliary electrode 140 may serve to electrically connect the transistor 120 and the light emitting diode 160. The auxiliary electrode 140 is electrically connected to the source electrode 123 of the transistor 120 through a contact hole formed in the first over coating layer 130. The auxiliary electrode 140 may be formed as a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof.

The second over coating layer 150 is disposed on the first over coating layer 130. The second over coating layer 150 is an insulating layer that planarizes upper portions of the first over coating layer 130 and the auxiliary electrode 140. A contact hole which exposes the auxiliary electrode 140 is formed on the second over coating layer 150.

The second over coating layer 150 may be formed of one of acrylic resin, epoxy resin, phenol resin, polyamide resin, polyimide resin, unsaturated polyester resin, polyphenylene resin, polyphenylene sulfide resin, benzocyclobutene, and photoresist, but is not limited thereto.

The second over coating layer 150 includes a base portion 151 and a plurality of protrusions 152. As illustrated in FIG. 3, the base portion 151 and the plurality of protrusions 152 may be integrally formed. For example, the base portion 151 and the plurality of protrusions 152 may be formed of the same material to be simultaneously formed by the same process, for example, by a mask process, but are not limited thereto.

The base portion 151 is disposed on the first over coating layer 130. A top surface (or an upper surface) of the base portion 151 is parallel to the substrate 110. Therefore, a step generated due to components disposed there below may be planarized by the base portion 151.

The plurality of protrusions 152 is disposed on the base portion 151. The plurality of protrusions 152 are integrally formed with the base portion 151 and protrude from the base portion 151. That is, the protrusions 152 protrude from the base portion 151 in a direction away from the substrate 110. Top surfaces of the plurality of protrusions 152 may be smaller than bottom surfaces, but are not limited thereto. That is, a top surface of a protrusion 152 has a width that is less than a bottom portion of the protrusion 152 that extends from the base portion 151.

Each of the plurality of protrusions 152 includes a top surface and a side surface that extends from the top surface. The top surface of the protrusion 152 is a surface located on an uppermost portion of the protrusion 152 and may be a surface substantially parallel to the base portion 151 or the substrate 110. The side surface of the protrusion 152 may be a surface which connects the top surface of the protrusion 152 and the base portion 151. The side surface has a first end that is connected to the top surface of the protrusion 152 and a second end that is connected to the base portion 151. The side surface of the protrusion 152 may be inclined toward the base portion 151. At this time, the side surface of the protrusion 152 may be disposed at a third angle 03 with respect to the top surface of the base portion 151, as shown in FIG. 4. For example, the side surface of the protrusion 152 may be disposed to form an inclination angle in a range of 55° to 70° with the top surface of the base portion 151, but is not limited thereto.

The light emitting diode 160 is disposed on the second over coating layer 150. The light emitting diode 160 includes a first electrode 161 which is electrically connected to the source electrode 123 of the transistor 120, an organic layer 162 disposed on the first electrode 161, and a second electrode 163 formed on the organic layer 162.

The first electrode 161 is disposed so as to correspond to each of the plurality of sub pixels SP. The first electrode 161 is disposed so as to cover the base portion 151 and a part of the plurality of protrusions 152. The first electrode 161 may be disposed along shapes of the base portion 151 and the plurality of protrusions 152 of the second over coating layer 150. Specifically, the first electrode 161 may be disposed on the top surface of the base portion 151 in which the protrusion 152 is not disposed and side surfaces of the plurality of protrusions 152. That is, the first electrode 161 is disposed along the shapes of the base portion 151 and the protrusions 152. Further, the first electrode 161 may be formed in a partial area of the top surface of the plurality of protrusions 152.

The first electrode 161 may be an anode of the light emitting diode 160. The first electrode 161 is electrically connected to the auxiliary electrode 140 through the contact hole which is formed in the second over coating layer 150. The first electrode 161 may be electrically connected to the source electrode 123 of the transistor 120 through the auxiliary electrode 140. However, the first electrode 161 may be configured to be electrically connected to the drain electrode 124 of the transistor 120 depending on a type of the transistor 120 and a design manner of the driving circuit.

Even though in FIG. 3, the first electrode 161 is illustrated as a single layer, the first electrode 161 may be configured as a multi-layer. For example, the first electrode 161 may include a reflective layer which reflects light emitted from the organic layer 162 toward the second electrode 163 and a transparent conductive layer which supplies holes to the organic layer 162.

The reflective layer is disposed on the second over coating layer 150 to reflect light emitted from the light emitting diode 160 upwardly. The light generated in the organic layer 162 of the light emitting diode 160 may be emitted not only upwardly, but also laterally. The light which is laterally emitted may be directed to the inside of the display apparatus 100 or trapped in the display apparatus 100 due to the total reflection, or further travel to the inside of the display apparatus 100 and then disappear. Therefore, the reflective layer is disposed below the organic layer 162 to cover side portions of the plurality of protrusions 152 to change a traveling direction of the light which is directed to a side portion of the organic layer 162 to a front direction.

The reflective layer may be formed of a metal material such as aluminum (Al), silver (Ag), copper (Cu), and a magnesium-silver alloy (Mg:Ag), but is not limited thereto.

The transparent conductive layer is disposed on the reflective layer. The transparent conductive layer may be formed of a conductive material having a high work function to supply holes to the organic layer 162. For example, the transparent conductive layer may be formed of transparent conductive oxide such as indium tin oxide (ITO), indium zinc oxide (IZO), indium tin zinc oxide (ITZO), zinc oxide (ZnO), and tin oxide (TO), but is not limited thereto.

The bank 170 is disposed on the second over coating layer 150 and the first electrode 161 so as to expose a part of the first electrode 161 and the protrusions 152. The bank 170 is an insulating layer which separates adjacent sub pixels SP. The bank 170 is disposed so as to open a part of the first electrode 161 to form an open area and forms a non-open area which covers a part of the first electrode 161 to define the emission area EA and the non-emission area NEA. In the meantime, the side surface of the bank 170 may be disposed at a predetermined fourth angle θ4 with respect to the top surface of the base portion 151. For example, the side surface of the bank 170 may be disposed to form an inclination angle of 40° to 60° with the top surface of the base portion 151, but is not limited thereto.

The emission area EA may refer to an area in which light is directly generated by the organic layer 162 in each of the plurality of sub pixels SP. The emission area EA is an opening area of the bank 170 so that the bank 170 is not disposed and the organic layer 162 is disposed directly on the first electrode 161 to generate light. The emission area EA may be divided into an emission area of a red sub pixel SPR, an emission area of a blue sub pixel SPB, and an emission area of a green sub pixel SPG.

The non-emission area NEA may refer to an area in which the light is not directly generated. The non-emission area NEA is a non-opening area of the bank 170 so that the bank 170 is disposed between the first electrode 161 and the organic layer 162 to block direct generation of light.

The non-emission area NEA may include a reflection area. Here, the reflection area is an area corresponding to a side surface of the bank 170 in which the first electrode 161 is disposed. In the reflection area, the reflective layer of the first electrode 161 formed on the side portion of the protrusion 152 serves as a side mirror so that some of light which may be trapped in the display apparatus 100 by the total reflection is extracted to the outside of the display apparatus 100. The reflection area may be divided into a reflection area of a red sub pixel SPR, a reflection area of a blue sub pixel SPB, and a reflection area of a green sub pixel SPG.

The bank 170 may be formed of an inorganic material. For example, the bank 170 may be formed of a single layer of silicon nitride (SiNx) or silicon oxide (SiOx) or multiple layers of silicon nitride (SiNx) and silicon oxide (SiOx). However, it is not limited thereto and the bank 170 may be formed of an organic material.

The organic layer 162 is disposed on the first electrode 161 and the bank 170. For example, the organic layer 162 is disposed on the first electrode 161 in the emission area EA and is disposed on the bank 170 in the non-emission area NEA. The organic layer 162 may be disposed along the shapes of the first electrode 161 and the bank 170. The organic layer 162 includes an emission layer and a common layer.

The emission layer is an organic layer which emits light with a specific color. Different emission layers may be disposed in the plurality of sub pixels SP or the same emission layer may be disposed in all the plurality of sub pixels SP. For example, when different emission layers are disposed in the plurality of sub pixels SP, a red emission layer may be disposed in a red sub pixel SPR, a green emission layer may be disposed in the green sub pixel SPG, and a blue emission layer may be disposed in the blue sub pixel SPB. When the same emission layer is disposed in all the plurality of sub pixels SP, light from the emission layer may be converted to various color light through a separate light conversion layer and a color filter.

The common layer is an organic layer which is disposed to improve the luminous efficiency of the emission layer. The common layer may be formed as the same layer over the plurality of sub pixels SP. That is, the common layers of the plurality of sub pixels SP may be simultaneously formed with the same material by the same process. The common layer may include a hole injection layer, a hole transport layer, an electron transport layer, an electron injection layer, and a charge generation layer, but is not limited thereto.

The second electrode 163 is disposed on the organic layer 162. The second electrode 163 may be disposed along the shape of the organic layer 162. The second electrode 163 supplies electrons to the organic layer 162 so that the second electrode may be formed of a conductive material having a low work function. The second electrode 163 may be a cathode of the light emitting diode 160. The second electrode 163 may be formed of a transparent conductive material such as indium tin oxide (ITO) or indium zinc oxide (IZO), or a metal alloy such as MgAg or a ytterbium (Yb) alloy and may further include a metal doping layer, but is not limited thereto. In the meantime, even though it is not illustrated in the drawing, the second electrode 163 is electrically connected to a low potential power line to be supplied with a low potential power signal.

An encapsulation unit 180 may be formed on the light emitting diode 160 to protect the light emitting diode 160 which is vulnerable to moisture so as not to be exposed to the moisture. The encapsulation unit 180 may block the oxygen and moisture which penetrate into the light emitting display apparatus 100 from the outside. For example, when the light emitting display apparatus 100 is exposed to the moisture or oxygen, a pixel shrink phenomenon that the emission area is shrunk may occur or a dead pixel in the emission area may be generated. Therefore, the encapsulation unit 180 blocks the oxygen and moisture to protect the light emitting display apparatus 100. For example, the encapsulation unit 180 may have a structure in which inorganic layers and organic layers are alternately laminated, but is not limited thereto.

Referring to FIG. 3, the encapsulation unit 180 includes a first inorganic encapsulation layer 181, a first organic encapsulation layer 182a, a second organic encapsulation layer 182b, and a second inorganic encapsulation layer 183.

The first inorganic encapsulation layer 181 is disposed on the second electrode 163 to suppress the permeation of the moisture or oxygen. The first inorganic encapsulating layer 181 may be formed of an inorganic material such as silicon nitride (SiNx), silicon oxynitride (SiNxOy), or aluminum oxide (AlyOz), but is not limited thereto. The first inorganic encapsulation layer 181 may be formed of a material having a refractive index that is higher than a refractive index of the first organic encapsulation layer 182a and the second organic encapsulation layer 182b.

The first organic encapsulation layer 182a is disposed on the first inorganic encapsulation layer 181 to planarize the surface of the first inorganic encapsulation layer 181. Further, the first organic encapsulation layer 182a may cover foreign materials or particles which may be generated during a manufacturing process. The first organic encapsulation layer 182a may be formed of an organic material, for example, polyimide, polycarbonate, acryl, or epoxy-based resin, but is not limited thereto. In one embodiment, the refractive index of the first organic encapsulation layer 182a may be 1.7 or higher.

The first organic encapsulation layer 182a includes a concave portion 182ad disposed so as to correspond to each of the plurality of sub pixels SP. The concave portion 182ad may be disposed so as to correspond to the first electrode 161 exposed from the bank 170. The concave portion 182ad is disposed so as to overlap an area in which the first electrode 161 is exposed from the bank 170, that is, the first emission area EA1 of the sub pixel SP. That is, the concave portion 182ad overlaps the portion of the first electrode 161 in the emission area EA1.

In the meantime, referring to FIG. 3, an end of the concave portion 182ad may be disposed so as to overlap flat top surfaces of the protrusion 152 and the bank 170. That is, the concave portion 182ad may be disposed to have a concave shape from the flat top surfaces of the protrusion 152 and the bank 170. A height of a trough of the concave portion 182ad from the upper surface of the substrate 110 is less than a height of an upper surface of the first organic encapsulation layer 182a.

The concave portion 182ad may be formed with a curved surface as illustrated in FIGS. 3 and 4. At this time, referring to FIG. 4, a first angle θ1 which is an angle formed by a top surface of the concave portion 182ad and the top surface of the base portion 151 may be 20° to 40°. That is, the top surface of the concave portion 182ad may be disposed to form an inclination angle of 20° to 40° with the top surface of the base portion 151.

The second organic encapsulation layer 182b is disposed on the first organic encapsulation layer 182a to planarize the surface together with the first organic encapsulation layer 182a. The second organic encapsulation layer 182b is in direct contact with the first organic encapsulation layer 182a. The second organic encapsulation layer 182b may have a refractive index that is different from a refractive index of the first organic encapsulation layer 182a. The second organic encapsulation layer 182a may have a refractive index that is lower than the refractive index of the first organic encapsulation layer 182a.

The second organic encapsulation layer 182b may be formed of an organic material, for example, polyimide, polycarbonate, acryl, or epoxy-based resin, but is not limited thereto. At this time, the refractive index of the second organic encapsulation layer 182b may be 1.4 or higher.

In the meantime, even though the first organic encapsulation layer 182a is formed of the same material as the second organic encapsulation layer 182b, the first organic encapsulation layer 182a may have a refractive index that is higher than the refractive index of the second organic encapsulation layer 182b. For example, a thermal treatment time for hardening the first organic encapsulation layer 182a is increased so that the first organic encapsulation layer 182a may have the refractive index to be higher than the refractive index of the second organic encapsulation layer 182b. However, the method for configuring the first organic encapsulation layer 182a and the second organic encapsulation layer 182b to have different refractive indices is not limited thereto.

In the meantime, referring to FIG. 3, light which is emitted toward the upper portion of the display apparatus 100 from the organic layer 162 passes through the first organic encapsulation layer 182a and the second organic encapsulation layer 182b to be refracted to the side direction of the sub pixel. For example, the first light L1 emitted toward the upper portion of the display apparatus 100 from the organic layer 162 may have a reduced traveling angle due to the difference of the refractive indices at the interface between the first organic encapsulation layer 182a having a higher refractive index and the second organic encapsulation layer 182b having a lower refractive index. Consequently, the first light L1 may be refracted to the side direction of the sub pixel.

Second light L2 which is reflected to the first electrode 161, among light emitted from the organic layer 162, also passes through the first organic encapsulation layer 182a and the second organic encapsulation layer 182b to be refracted to the side direction of the sub pixel. For example, the second light L2 reflected to the first electrode 161 from the organic layer 162 may have a reduced traveling angle due to the difference of the refractive indices at the interface between the first organic encapsulation layer 182a having a higher refractive index and the second organic encapsulation layer 182b having a lower refractive index. Consequently, the second light L2 may be refracted to the side direction of the sub pixel.

In the meantime, referring to FIG. 3, the first light L1 and the second light L2 may have a reduced traveling angle at the interface between the second organic encapsulation layer 182b and the second inorganic encapsulation layer 183. That is, the insulating layer such as the second inorganic encapsulation layer 183 disposed on the second organic encapsulation layer 182b may have a refractive index smaller than the refractive index of the second organic encapsulation layer 182b, but is not limited thereto.

The second inorganic encapsulation layer 183 is disposed on the second organic encapsulation layer 182b and may suppress the permeation of the moisture or oxygen, like the first inorganic encapsulation layer 181. The second inorganic encapsulation layer 183 may be formed of an inorganic material such as silicon nitride (SiNx), silicon oxynitride (SiNxOy), silicon oxide (SiOx), or aluminum oxide (AlyOz), but is not limited thereto. The second inorganic encapsulation layer 183 may be formed of the same material as the first inorganic encapsulation layer 181 or formed of a different material.

Referring to FIG. 3, the touch unit 190 is disposed on the encapsulation unit 180.

The touch unit 190 includes a touch buffer layer 191, a bridge electrode 192, a touch interlayer insulating layer 193, a touch electrode 194, and a passivation layer 195.

The touch unit 190 is a configuration for touch sensing and for example, at the intersection of the touch driving line and the touch sensing line, a mutual capacitance Cm is formed to charge electric charges by a touch driving signal applied to the touch driving line and discharge the charged electric charges to the touch sensing line. By doing this, the touch unit 190 may serve as a touch sensor.

The touch buffer layer 191 is disposed on the second inorganic encapsulation layer 183. The touch buffer layer 191 may be formed of an inorganic material such as silicon nitride (SiNx), silicon oxynitride (SiNxOy), silicon oxide (SiOx), or aluminum oxide (AlyOz), but is not limited thereto.

The plurality of touch electrodes 194 may be disposed along a first direction or a second direction intersecting the first direction to be spaced apart from each other with a predetermined interval. The plurality of bridge electrodes 192 is disposed on a different layer from that of the plurality of touch electrodes 194 to be electrically connected to the plurality of touch electrodes 194 through a contact hole.

The touch interlayer insulating layer 193 is disposed between the bridge electrode 192 and the touch electrode 194. The touch interlayer insulating layer 193 may be formed of an organic material or an inorganic material. For example, the touch interlayer insulating layer 193 may be formed of an inorganic material such as silicon nitride (SiNx), silicon oxynitride (SiNxOy), silicon oxide (SiOx), or aluminum oxide (AlyOz), but is not limited thereto.

The passivation layer 195 is disposed on the touch electrode 194. The passivation layer 195 is configured to insulate components above the touch electrode 194. For example, the passivation layer 195 may be formed of an inorganic material such as silicon nitride (SiNx), silicon oxynitride (SiNxOy), silicon oxide (SiOx), or aluminum oxide (AlyOz), but is not limited thereto.

Referring to FIG. 3, the black matrix BM is disposed on the touch unit 190. The black matrix BM is disposed between the plurality of sub pixels SP which emits light with different wavelength bands to reduce color mixture between the sub pixels SP. For example, the black matrix BM may be formed of chrome (Cr) or other opaque metal film, or resin, but is not limited thereto.

Referring to FIG. 3, the color filter CF is disposed on the touch unit 190 and the black matrix BM. The color filter CF may be disposed so as to overlap the first electrode 161 which is exposed by the bank 170. That is, the color filter CF is disposed so as to overlap the area of the first electrode 161 which is exposed by the bank 170, that is, an opening area to overlap the entire area of the emission area EA.

The color filter CF may include a red color filter CFR overlapping the emission area of the red sub pixel SPR, a green color filter CFG overlapping the emission area of the green sub pixel SPG, and a blue color filter CFB overlapping the emission area of the blue sub pixel SPB. Further, the red color filter CFR may overlap the entire emission area of the red sub pixel SPR, the green color filter CFG may overlap the entire emission area of the green sub pixel SPG, and the blue color filter CFB may overlap the entire emission area of the blue sub pixel SPB.

The color filter CF may be formed by dispersing a dye which absorbs light of a specific wavelength band into a base resin. However, it is not limited thereto and the color filter CF may be implemented by various materials. The color filter CF may emit only light having a specific wavelength band, but blocks light having an undesired wavelength band so as not to be emitted so that an amount of light which passes through the color filter CF to be extracted may be reduced in comparison with an amount of light before passing through the color filter CF.

In the meantime, referring to FIG. 3, each of the plurality of sub pixels SP includes an emission area EA and a non-emission area NEA. For example, the emission area EA includes a first emission area EA1 and a second emission area EA2 and the non-emission area NEA includes a first non-emission area NEA1 and a second non-emission area NEA2. For example, the first emission area EA1, the first non-emission area NEA1, the second emission area EA2, and the second non-emission area NEA2 may be defined by the bank 170.

The first emission area EA1 corresponds to an area in which the first electrode 161 is exposed from the bank 170. The first emission area EA1 may correspond to the concave portion 182ad. That is, the first emission area EA1 overlaps the concave portion 182ad. The first emission area EA1 may refer to an area in which light is substantially generated by the organic layer 162 in each of the plurality of sub pixels SP. In the first emission area EA1, the bank 170 is not disposed and the organic layer 162 is located directly on the first electrode 161 to generate light.

The first non-emission area NEA1 encloses the first emission area EA1 and may correspond to an area where the bank 170 is disposed on the first electrode 161 that is on the base portion 151. At this time, the first non-emission area NEA1 may correspond to an area which does not overlap (e.g., non-overlapping) the side surface of the protrusion 152. When the display apparatus 100 is on, the first non-emission area NEA1 may be in a black state or have a luminance lower than those of the first emission area EA1 and the second emission area EA2 due to light incident from at least one of the first emission area EA1 and the second emission area EA2.

The second emission area EA2 encloses the first non-emission area NEA1 and may correspond to the side surface of the protrusion 152. The second emission area EA2 may be an area in which some of light emitted from the organic layer 162 is reflected by the first electrode 161 disposed on the inclined side surface of the protrusion 152 to be extracted to the outside of the display apparatus 100. Further, the luminance of the second emission area EA2 may be lower than the luminance of the first emission area EA1, but is not limited thereto.

The second non-emission area NEA2 encloses the second emission area EA2 and may correspond to a flat top surface of the protrusion 152. The second non-emission area NEA2 may be disposed so as to enclose the second emission area EA2 on a top surface of the protrusion 152. The second non-emission area NEA2 may be an area in which components for driving the emission area EA are disposed. An end of the concave portion 182ad may be disposed so as to overlap the second non-emission area NEA2.

When the display apparatus 100 is on, the second non-emission area NEA2 may be in a black state or have a luminance lower than those of the first emission area EA1 and the second emission area EA2 due to light incident from at least one of the first emission area EA1 and the second emission area EA2. Further, when the luminance of the second non-emission area NEA2 is lower than the luminance of each of the first emission area EA1 and the second emission area EA2, the luminance of the first non-emission area NEA1 may be higher than the luminance of the second non-emission area NEA2, but is not limited thereto.

Hereinafter, a manufacturing process of a display apparatus 100 according to an exemplary embodiment of the present disclosure will be described with reference to FIGS. 5A to 5D.

FIGS. 5A to 5D are process flowcharts of a display apparatus according to an exemplary embodiment of the present disclosure.

First, referring to FIG. 5A, a material 182a′ for forming the first organic encapsulation layer 182a is disposed on the first inorganic encapsulation layer 181 corresponding to the flat top surface of the bank 170 using inkjet printing.

Next, referring to FIG. 5B, the material 182a′ for forming the first organic encapsulation layer 182a is spread along the inclined side surface of the bank 170. Therefore, the material 182a′ for forming the first organic encapsulation layer 182a may move downwardly while flowing down along the side surface of the bank 170.

Next, referring to FIG. 5C, the material 182a′ for forming the first organic encapsulation layer 182a moves from the bank 170 toward an area where the first electrode 161 is exposed to be filled in the concave area of the sub pixel SP to form the first organic encapsulation layer 182a. At this time, in the first organic encapsulation layer 182a, the concave portion 182ad having a concave top surface may be disposed. The thermal treatment process for hardening the material 182a′ for forming the first organic encapsulation layer 182a may be performed. In the meantime, the thermal treatment process for forming the first organic encapsulation layer 182a may be performed longer than the thermal treatment process for forming the second organic encapsulation layer 182b so that the first organic encapsulation layer 182a may have a refractive index higher than that of the second organic encapsulation layer 182b.

Finally, referring to FIG. 5D, the second organic encapsulation layer 182b having a refractive index lower than the refractive index of the first organic encapsulation layer 182a is disposed on the first organic encapsulation layer 182a. The touch unit 190, the black matrix BM, and the color filter CF are disposed on the second organic encapsulation layer 182b to complete the manufacturing process of the display apparatus 100.

The display apparatus in which a side surface of an anode is disposed on an inclined surface to be used as a reflection surface is advantageous in that light emitted from the light emitting diode is reflected from the inclined side surface of the anode to improve the light extraction efficiency. However, in the case of light emitted as described above, an amount of light emitted to the front direction is increased so that light emitted to the side direction is relatively reduced to cause a problem in that a luminance viewing angle is reduced.

In the display apparatus 100 according to the exemplary embodiment of the present disclosure, the second organic encapsulation layer 182b having a refractive index lower than the refractive index of the first organic encapsulation layer 182a is disposed on the first organic encapsulation layer 182a including the concave portion 182ad. By doing this, the viewing angle of the display apparatus 100 may be improved.

Specifically, in the first organic encapsulation layer 182a, the concave portion 182ad is disposed so as to correspond to an area in which the first electrode 161 is exposed from the bank 170, that is, the first emission area EA1 of the sub pixel. Further, the second organic encapsulation layer 182b having a refractive index lower than the refractive index of the first organic encapsulation layer 182a is disposed on the first organic encapsulation layer 182a. Therefore, first light which is emitted toward the upper portion of the display apparatus 100 from the organic layer 162 passes through the first organic encapsulation layer 182a and the second organic encapsulation layer 182b to be refracted to the side direction of the sub pixel. Second light which is reflected to the first electrode 161, among light emitted from the organic layer 162, also passes through the first organic encapsulation layer 182a and the second organic encapsulation layer 182b to be refracted to the side direction of the sub pixel. That is, the path of light emitted from the organic layer 162 is refracted to the side direction of the sub pixel to improve the viewing angle of the display apparatus 100. Accordingly, in the display apparatus 100 according to the exemplary embodiment of the present disclosure, the second organic encapsulation layer 182b having a refractive index lower than the refractive index of the first organic encapsulation layer 182a is disposed on the first organic encapsulation layer 182a including the concave portion 182ad. By doing this, the viewing angle of the display apparatus 100 may be improved and the luminance deviation according to the viewing angle is reduced to improve the display quality of the display apparatus.

FIG. 6 is a cross-sectional view of a display apparatus according to another exemplary embodiment of the present disclosure. FIG. 7 is an enlarged cross-sectional view of one sub pixel of a display apparatus according to another exemplary embodiment of the present disclosure. The only difference between a display apparatus 600 of FIG. 6 and the display apparatus 100 of FIGS. 1 to 5D is a shape of a concave portion 682ad, but the other configurations are substantially the same, so that a redundant description will be omitted.

Referring to FIGS. 6 and 7, a concave portion 682ad of a first organic encapsulation layer 682a may be configured by a flat bottom surface and a side surface having a predetermined inclination angle. That is, the side surface of the concave portion 682ad may be disposed at a predetermined angle with respect to the top surface of the base portion 151.

In the meantime, referring to FIG. 7, the side surface of the concave portion 682ad may be disposed at a predetermined second angle θ2 with respect to the top surface of the base portion 151. For example, the second angle θ2 may be disposed to form an inclination angle of 40° to 70°, but is not limited thereto.

Hereinafter, a manufacturing process of a display apparatus 600 according to an exemplary embodiment of the present disclosure will be described with reference to FIGS. 8A to 8C.

FIGS. 8A to 8C are process flowcharts of a display apparatus according to another exemplary embodiment of the present disclosure.

First, referring to FIG. 8A, a material 682a′ for forming the first organic encapsulation layer 682a is disposed on the first inorganic encapsulation layer 181 corresponding to the flat top surface of the bank 170. A mask is disposed on the material 682a′ for forming the first organic encapsulation layer 682a and, for example, is exposed to the ultraviolet ray UV and then a photoresist process of etching the material 682a′ for forming the first organic encapsulation layer 682a is performed.

Next, referring to FIG. 8B, the thermal treatment process for hardening the material 682a′ for forming the first organic encapsulation layer 682a to which the photoresist process is performed may be performed. Therefore, as illustrated in FIG. 8B, a concave portion 682ad having an angular cross-sectional shape may be patterned. In the meantime, the thermal treatment process for forming the first organic encapsulation layer 682a may be performed longer than the thermal treatment process for forming the second organic encapsulation layer 682b so that the first organic encapsulation layer 682a may have a refractive index higher than that of the second organic encapsulation layer 682b.

Finally, the second organic encapsulation layer 682b having a refractive index lower than that of the first organic encapsulation layer 682a is disposed on the first organic encapsulation layer 682a. The touch unit 190, the black matrix BM, and the color filter CF are disposed on the second organic encapsulation layer 682b to complete the manufacturing process of the display apparatus 600, as shown in FIG. 8C.

In the display apparatus 600 according to another exemplary embodiment of the present disclosure, the second organic encapsulation layer 682b having a refractive index lower than that of the first organic encapsulation layer 682a is disposed on the first organic encapsulation layer 682a including the concave portion 682ad. By doing this, the viewing angle of the display apparatus 600 may be improved.

Specifically, in the first organic encapsulation layer 682a of the encapsulation unit 680, the concave portion 682ad is disposed so as to correspond to an area in which the first electrode 161 is exposed from the bank 170, that is, the first emission area EA1 of the sub pixel. Further, the second organic encapsulation layer 682b having a refractive index lower than that of the first organic encapsulation layer 682a is disposed on the first organic encapsulation layer 682a. Therefore, first light which is emitted toward the upper portion of the display apparatus 100 from the organic layer 162 passes through the first organic encapsulation layer 682a and the second organic encapsulation layer 682b to be refracted to the side direction of the sub pixel. Second light which is reflected to the first electrode 161, among light emitted from the organic layer 162, also passes through the first organic encapsulation layer 682a and the second organic encapsulation layer 682b to be refracted to the side direction of the sub pixel. That is, the path of light emitted from the organic layer 162 is refracted to the side direction of the sub pixel to improve the viewing angle of the display apparatus 600. Accordingly, in the display apparatus 600 according to another exemplary embodiment of the present disclosure, the second organic encapsulation layer 682b having a refractive index lower than that of the first organic encapsulation layer 682a is disposed on the first organic encapsulation layer 682a including the concave portion 682ad. By doing this, the viewing angle of the display apparatus 600 may be improved and the luminance deviation according to the viewing angle is reduced to improve the display quality of the display apparatus.

The exemplary embodiments of the present disclosure can also be described as follows:

In one embodiment, a display apparatus comprises: a substrate including a plurality of sub pixels; an over coating layer on the substrate, the over coating layer including a base portion and a protrusion that protrudes from the base portion in a direction away from the substrate and has an inclined side surface with respect to the base portion; a first electrode in a sub pixel from the plurality of sub pixels, the first electrode covering a part of the base portion and a part of the protrusion; a bank on the first electrode and the protrusion, the bank having an opening that exposes a part of the first electrode; an organic layer on the first electrode and the bank; a second electrode on the organic layer; and an encapsulation unit on the second electrode, the encapsulation unit including a first inorganic encapsulation layer on the second electrode, a first organic encapsulation layer on the first inorganic encapsulation layer, a second organic encapsulation layer on the first organic encapsulation layer, and a second inorganic encapsulation layer on the second organic encapsulation layer, wherein a refractive index of the second organic encapsulation layer is different from a refractive index of the first organic encapsulation layer, wherein the first organic encapsulation layer includes a concave portion that overlaps the exposed part of first electrode.

In one embodiment, the refractive index of the second organic encapsulation layer is less than the refractive index of the first organic encapsulation layer.

In one embodiment, the refractive index of the first organic encapsulation layer is 1.7 or higher and the refractive index of the second organic encapsulation layer is 1.4 or higher.

In one embodiment, an end of the concave portion overlaps a top surface of the protrusion.

In one embodiment, the concave portion has a curved surface.

In one embodiment, a top surface of the concave portion has an inclination angle in a range of 20° to 40° with respect to a top surface of the base portion.

In one embodiment, the concave portion has a flat bottom surface and a side surface having an inclination angle with respect to a top surface of the base portion.

In one embodiment, the inclination angle of the side surface is in a range of 40° to 70° with respect to the top surface of the base portion.

In one embodiment, the sub pixel includes a first emission area corresponding to an area where the part of the first electrode is exposed from the bank; a first non-emission area that encloses the first emission area, the first non-emission area corresponding to an area where the bank is on the first electrode that is on the base portion; a second emission area that encloses the first non-emission area, the second emission area corresponding to the inclined side surface of the protrusion; and a second non-emission area that encloses the second emission area, the second non-emission area corresponding to a top surface of the protrusion.

In one embodiment, a display apparatus comprises: a substrate including an active area in which a plurality of sub pixels are disposed and a non-active area; an over coating layer on the substrate, the over coating layer including a base portion and a protrusion that protrudes from the base portion in a direction away from the substrate and has an inclined side surface; a first electrode in a sub pixel from the plurality of sub pixels, the first electrode covering the base portion and a part of the protrusion; a bank on the first electrode, the bank having an opening that exposes a part of the first electrode; an organic layer on the first electrode and the bank; a second electrode on the organic layer; and an encapsulation unit on the second electrode, the encapsulation unit including a first inorganic encapsulation layer on the second electrode, a first organic encapsulation layer on the first inorganic encapsulation layer, a second organic encapsulation layer on the first organic encapsulation layer and having a refractive index that is lower than a refractive index of the first organic encapsulation layer, and a second inorganic encapsulation layer on the second organic encapsulation layer, wherein the sub pixel includes a first emission area corresponding to an area where the part of the first electrode is exposed from the bank, and wherein the first organic encapsulation layer includes a concave portion that overlaps the exposed part of first electrode.

In one embodiment, the sub pixel further includes a first non-emission area that encloses the first emission area, the first non-emission area corresponding to an area where the bank is on the first electrode that is on the base portion; a second emission area that encloses the first non-emission area, the second emission area corresponding to the inclined side surface of the protrusion; and a second non-emission area that encloses the second emission area, the second non-emission area corresponding to a top surface of the protrusion, and an end of the concave portion overlaps the second non-emission area.

In one embodiment, the refractive index of the first organic encapsulation layer is 1.7 or higher and the refractive index of the second organic encapsulation layer is 1.4 or higher.

In one embodiment, the concave portion has a curved surface.

In one embodiment, a top surface of the concave portion has an inclination angle in a range of 20° to 40° with respect to a top surface of the base portion.

In one embodiment, the concave portion includes a flat bottom surface and a side surface having an inclination angle with respect to a top surface of the base portion.

In one embodiment, the inclination angle of the side surface is in a range of 40° to 70° with respect to the top surface of the base portion.

In one embodiment, a display apparatus comprises: a substrate; a transistor on the substrate; a light-emitting element that is electrically connected to the transistor, the light-emitting element including a first electrode, an organic layer on the first electrode, and a second electrode on the organic layer; a bank on the first electrode of the light-emitting element, the bank including an opening that exposes a part of the first electrode; and an encapsulation unit over the light-emitting element, the encapsulation unit including a first inorganic encapsulation layer on the second electrode of the light-emitting element, a first organic encapsulation layer on the first inorganic encapsulation layer that has a concave portion that extends in a direction toward the substrate, a second organic encapsulation layer on the concave portion of the first inorganic encapsulation layer, and a second inorganic encapsulation layer on the second organic encapsulation layer, wherein the concave portion of the first organic encapsulation layer overlaps the exposed part of the first electrode.

In one embodiment, the sub pixel further includes a first non-emission area that encloses the first emission area, the first non-emission area corresponding to an area where the bank is on the first electrode that is on the base portion; a second emission area that encloses the first non-emission area, the second emission area corresponding to the inclined side surface of the protrusion; and a second non-emission area that encloses the second emission area, the second non-emission area corresponding to a top surface of the protrusion, and an end of the concave portion overlaps the second non-emission area.

In one embodiment, the refractive index of the first organic encapsulation layer is 1.7 or higher and the refractive index of the second organic encapsulation layer is 1.4 or higher.

In one embodiment, the concave portion has a curved surface.

In one embodiment, a top surface of the concave portion has an inclination angle in a range of 20° to 40° with respect to a top surface of the base portion.

In one embodiment, the concave portion includes a flat bottom surface and a side surface having an inclination angle with respect to a top surface of the base portion.

In one embodiment, the inclination angle of the side surface is in a range of 40° to 70° with respect to the top surface of the base portion.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display apparatus comprising:
a substrate including a plurality of sub pixels;
an over coating layer on the substrate, the over coating layer including a base portion and a protrusion that protrudes from the base portion in a direction away from the substrate and has an inclined side surface with respect to the base portion;
a first electrode in a sub pixel from the plurality of sub pixels, the first electrode covering a part of the base portion and a part of the protrusion;
a bank on the first electrode and the protrusion, the bank having an opening that exposes a part of the first electrode;
an organic layer on the first electrode and the bank;
a second electrode on the organic layer; and
an encapsulation unit on the second electrode, the encapsulation unit including a first inorganic encapsulation layer on the second electrode, a first organic encapsulation layer on the first inorganic encapsulation layer, a second organic encapsulation layer on the first organic encapsulation layer, and a second inorganic encapsulation layer on the second organic encapsulation layer,
wherein a refractive index of the second organic encapsulation layer is different from a refractive index of the first organic encapsulation layer,
wherein the first organic encapsulation layer includes a concave portion that overlaps the exposed part of first electrode.

2. The display apparatus according to claim 1, wherein the refractive index of the second organic encapsulation layer is less than the refractive index of the first organic encapsulation layer.

3. The display apparatus according to claim 2, wherein the refractive index of the first organic encapsulation layer is 1.7 or higher and the refractive index of the second organic encapsulation layer is 1.4 or higher.

4. The display apparatus according to claim 1, wherein an end of the concave portion overlaps a top surface of the protrusion.

5. The display apparatus according to claim 1, wherein the concave portion has a curved surface.

6. The display apparatus according to claim 5, wherein a top surface of the concave portion has an inclination angle in a range of 20° to 40° with respect to a top surface of the base portion.

7. The display apparatus according to claim 1, wherein the concave portion has a flat bottom surface and a side surface having an inclination angle with respect to a top surface of the base portion.

8. The display apparatus according to claim 7, wherein the inclination angle of the side surface is in a range of 40° to 70° with respect to the top surface of the base portion.

9. The display apparatus according to claim 1, wherein the sub pixel includes:
a first emission area corresponding to an area where the part of the first electrode is exposed from the bank;
a first non-emission area that encloses the first emission area, the first non-emission area corresponding to an area where the bank is on the first electrode that is on the base portion;
a second emission area that encloses the first non-emission area, the second emission area corresponding to the inclined side surface of the protrusion; and
a second non-emission area that encloses the second emission area, the second non-emission area corresponding to a top surface of the protrusion.

10. A display apparatus comprising:
a substrate including an active area in which a plurality of sub pixels are disposed and a non-active area;
an over coating layer on the substrate, the over coating layer including a base portion and a protrusion that protrudes from the base portion in a direction away from the substrate and has an inclined side surface;
a first electrode in a sub pixel from the plurality of sub pixels, the first electrode covering the base portion and a part of the protrusion;
a bank on the first electrode, the bank having an opening that exposes a part of the first electrode;
an organic layer on the first electrode and the bank;
a second electrode on the organic layer; and
an encapsulation unit on the second electrode, the encapsulation unit including a first inorganic encapsulation layer on the second electrode, a first organic encapsulation layer on the first inorganic encapsulation layer, a second organic encapsulation layer on the first organic encapsulation layer and having a refractive index that is lower than a refractive index of the first organic encapsulation layer, and a second inorganic encapsulation layer on the second organic encapsulation layer,
wherein the sub pixel includes a first emission area corresponding to an area where the part of the first electrode is exposed from the bank, and
wherein the first organic encapsulation layer includes a concave portion that overlaps the exposed part of first electrode.

11. The display apparatus according to claim 10, wherein the sub pixel further includes:
a first non-emission area that encloses the first emission area, the first non-emission area corresponding to an area where the bank is on the first electrode that is on the base portion;
a second emission area that encloses the first non-emission area, the second emission area corresponding to the inclined side surface of the protrusion; and
a second non-emission area that encloses the second emission area, the second non-emission area corresponding to a top surface of the protrusion, and
an end of the concave portion overlaps the second non-emission area.

12. The display apparatus according to claim 10, wherein the refractive index of the first organic encapsulation layer is 1.7 or higher and the refractive index of the second organic encapsulation layer is 1.4 or higher.

13. The display apparatus according to claim 10, wherein the concave portion has a curved surface.

14. The display apparatus according to claim 13, wherein a top surface of the concave portion has an inclination angle in a range of 20° to 40° with respect to a top surface of the base portion.

15. The display apparatus according to claim 10, wherein the concave portion includes a flat bottom surface and a side surface having an inclination angle with respect to a top surface of the base portion.

16. The display apparatus according to claim 15, wherein the inclination angle of the side surface is in a range of 40° to 70° with respect to the top surface of the base portion.

17. A display apparatus comprising:
a substrate;
a transistor on the substrate;
a light-emitting element that is electrically connected to the transistor, the light-emitting element including a first electrode, an organic layer on the first electrode, and a second electrode on the organic layer;
a bank on the first electrode of the light-emitting element, the bank including an opening that exposes a part of the first electrode; and
an encapsulation unit over the light-emitting element, the encapsulation unit including a first inorganic encapsulation layer on the second electrode of the light-emitting element, a first organic encapsulation layer on the first inorganic encapsulation layer that has a concave portion that extends in a direction toward the substrate, a second organic encapsulation layer on the concave portion of the first inorganic encapsulation layer, and a second inorganic encapsulation layer on the second organic encapsulation layer,
wherein the concave portion of the first organic encapsulation layer overlaps the exposed part of the first electrode.

18. The display apparatus according to claim 17, wherein a refractive index of the second organic encapsulation layer is different from a refractive index of the first organic encapsulation layer.

19. The display apparatus according to claim 18, wherein the refractive index of the second organic encapsulation layer is less than the refractive index of the first organic encapsulation layer.

20. The display apparatus of claim 18, wherein the first organic encapsulation layer and the second organic encapsulation layer have a same material.

21. The display apparatus of claim 17, wherein the concave portion of the first organic encapsulation layer has a curved surface.

22. The display apparatus of claim 17, wherein the concave portion of the first organic encapsulation layer includes a flat bottom surface and a side surface that is connected to the flat bottom surface, the side surface having an inclination angle with respect to the substrate.

23. The display apparatus of claim 17, further comprising:
an over coating layer between the transistor and the light-emitting element, the over coating layer including a base portion and a protrusion that protrudes from the base portion in a direction away from the substrate and has an inclined side surface.

24. The display apparatus of claim 23, wherein the first electrode is on the inclined side surface of the protrusion.

25. The display apparatus of claim 23, wherein a height of a part of the first organic encapsulation layer that overlaps the protrusion is higher than a height of a trough of the concave portion that overlaps the exposed part of the first electrode.
